(19) United States
(12) Patent Application Publication
(10) Pub. No.: US 2017/0236878 A1
(43) Pub. Date: Aug. 17, 2017

(54) PIXEL ARRAY, DISPLAY PANEL AND PIXEL STRUCTURE

(71) Applicant: EVERDISPLAY OPTRONICS (SHANGHAI) LIMITED, SHANGHAI CITY (CN)

(72) Inventors: Mingyue ZHANG, SHANGHAI CITY (CN); Hsin Chih LIN, SHANGHAI CITY (CN); Jr-Hong CHEN, SHANGHAI CITY (CN)

(73) Assignee: EVERDISPLAY OPTRONICS (SHANGHAI) LIMITED, SHANGHAI CITY (CN)

(21) Appl. No.: 15/145,165

(22) Filed: May 3, 2016

(30) Foreign Application Priority Data
Feb. 17, 2016 (CN) 201610088317.4

(51) Int. Cl. H01L 27/32

(52) U.S. Cl. CPC H01L 27/326

(57) ABSTRACT

A display panel, a pixel array and a pixel structure are provided in the present disclosure. The pixel array includes: a substrate; and a plurality of pixel units, each of the pixel units being disposed on the substrate and including: a first surface facing the substrate; a second surface opposite to the substrate; and a side wall connecting the first surface and the second surface, wherein the first surface has an area greater than that of the second surface, and light from each pixel unit exits from the second surface and the side wall.

### CROSS-REFERENCE TO RELATED APPLICATIONS

This application is based upon and claims priority to Chinese Patent Application 201610088317.4, filed on Feb. 17, 2016, the entire contents of which are incorporated herein by reference.

### TECHNICAL FIELD

The present disclosure relates to the field of display technology, and more particularly, to a pixel array, a display panel and a pixel structure.

### BACKGROUND

Recently, organic light emitting diode (OLED) technology is developing rapidly, and is becoming a most promising technology that will possibly replace liquid crystal displays (LCDs).

Pixels in the OLED display in the prior art have planer designs, causing the display to have a significant color shift at a large view angle, which is desiderated to be improved. Color shift is a difference between the displayed color and the real color generated due to weakness or strength of one or more colors. When the light exciting at a 0 (zero) degree view angle differs from the light exciting at a large view angle, the intensity and peak of the emitting spectrum are different, causing RGB brightness decay and spectrum blue shift. In addition, the RGB brightness decay and the spectrum blue shift are uneven, which further changes the brightness and color of the light exciting at the 0 degree view angle and at the large view angle, causing color distortion.

Referring to FIG. 1, FIG. 1 illustrates a schematic diagram of a display panel with a known planar pixel design. A planar pixel 120 is disposed on a substrate 110. Light emitted from the planar pixel 120 exits only in a direction perpendicular to the substrate, while cannot exit in other directions. The light exited from the substrate in a direction perpendicular to the substrate, when being viewed by the user at the 0 degree view angle, has a straight exiting surface as illustrated by the square 210. Light exited from the substrate in a direction perpendicular to the substrate is also visible to the user at a 45 degrees view angle, however, the viewed light has an inclined exiting surface as illustrated by the rectangular 220 since the light exited from the substrate in a direction perpendicular to the substrate has a certain angle with respect to the user's view angle. Since the angle between the user's view angle and the exited light is 45 degrees, a ratio between an area of the rectangular 220 to that of the square 210 is \sqrt{2}/2. FIGS. 2-4 illustrate the spectrums of the RGB three primary colors of the display panel shown in FIG. 1 at the 0 degree view angle and 45 degrees view angle. In particular, longitudinal axis of the graphs in FIGS. 2-4 represent spectrum intensities, the lateral axis thereof represent the wave lengths, the solid lines represent spectrum curves of the RGB three primary colors at the 0 degree view angle respectively, and the dashed lines represent spectrum curves of the RGB three primary colors at the 45 degrees view angle respectively. As can be seen form the spectrum diagrams illustrated in FIGS. 2-4, when the display is turned to the 45 degrees view angle from the 0 degree angle, 1) brightness of the RGB three primary colors decays significantly, and the percentages of the decay differ from one another, causing a misbalance among the brightness of the RGB three primary colors at large view angles; and 2) brightness peaks of the RGB three primary colors are blue shifted, causing color distortion of color generated by the RGB three primary colors.

In other words, if a screen image at the 0 degree view angle is taken as a standard image, color distortion may occur when the screen is viewed at another view angle (e.g., 30 degrees, 45 degrees or the like), and the color reproduction and the color saturation of the display may be deteriorated.

### SUMMARY

According to an aspect of the present disclosure, a pixel array including: a substrate; and a plurality of pixel units, each of the pixel units being disposed on the substrate and having a stereo shape, wherein each of the pixel unit includes: a first surface facing the substrate; a second surface opposite to the substrate; and a side wall connecting the first surface and the second surface, wherein the first surface has an area greater than that of the second surface, and light from each pixel unit exits from the second surface and the side wall.

According to another aspect of the present disclosure, there is further provided a display panel including: a substrate; a TFT element disposed on the substrate; a plurality of pixel units, each of which being disposed on the substrate and having a stereo shape, wherein each pixel unit includes: a first surface facing the substrate; a second surface opposite to the substrate; and a side wall connecting the first surface and the second surface, wherein the first surface has an area greater than that of the second surface, and light from each pixel unit exits from the second surface and the side wall.

According to another aspect of the present disclosure, there is further provided a pixel structure formed on a substrate of a display panel, including a first surface and a second surface parallel to one another and connected by a side wall, wherein the first surface has an area greater than that of the second surface, and the first surface is a pixel shape defining layer or a surface of a light emitting element.

### BRIEF DESCRIPTION OF THE DRAWINGS

The above and other features and advantages of the present disclosure will become more apparent by describing its example implementations in detail with reference to the drawings.

FIG. 1 illustrates a schematic diagram of a display panel in the prior art.

FIG. 2 illustrates a spectrum of the red pixels of the display panel in the prior art.

FIG. 3 illustrates a spectrum of the green pixels of the display panel in the prior art.

FIG. 4 illustrates a spectrum of the blue pixels of the display panel in the prior art.

FIG. 5 illustrates a schematic diagram of a pixel array according to embodiments of the present disclosure.

FIGS. 6A to 6C illustrate schematic diagrams of pixel units having various shapes according to embodiments of the present disclosure.

FIG. 7 illustrates a schematic diagram of a pixel unit at 0 degree view angle according to embodiments of the present disclosure.

FIG. 8 illustrates a schematic diagram of a pixel unit at 45 degrees view angle according to embodiments of the present disclosure.

FIG. 9 illustrates a schematic diagram of a pixel array according to an embodiment of the present disclosure.

FIG. 10 illustrates a schematic diagram of a display panel according to an embodiment of the present disclosure.

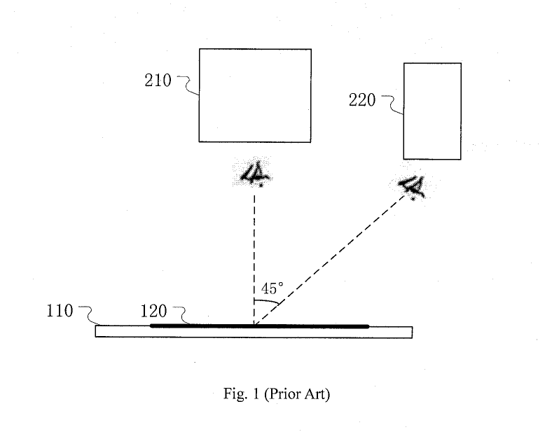

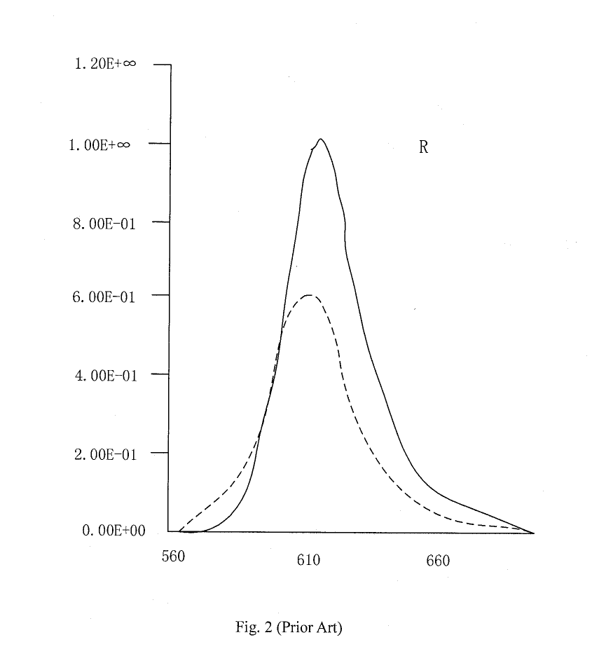

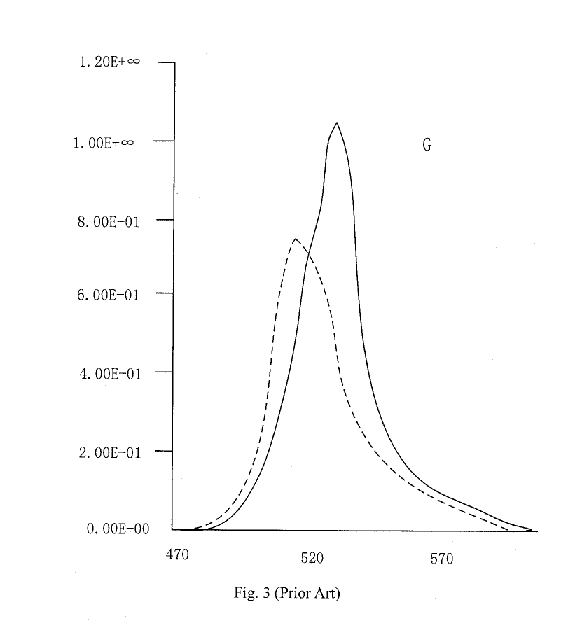

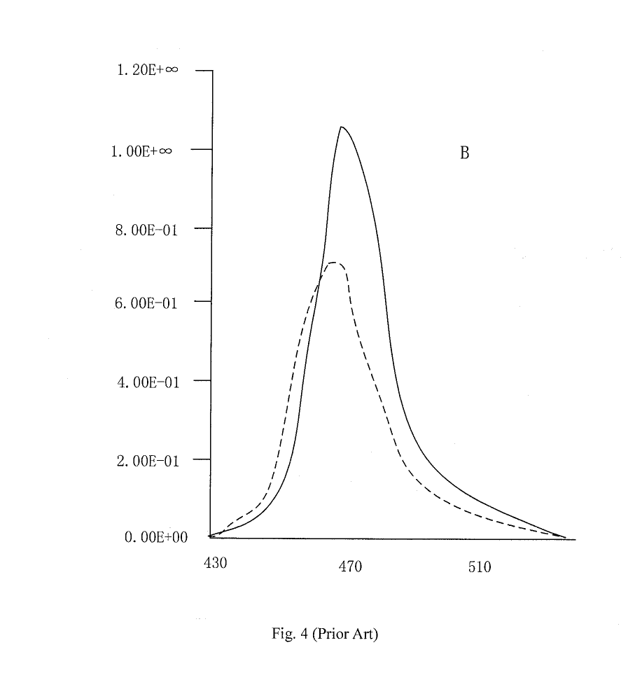

### DETAILED DESCRIPTION

Example implementations will be described in further detail with reference to the accompanying drawings. The example implementation, however, may be embodied in various forms, and should not be construed as being limited to the implementations described herein. Rather, these implementations are provided so that the present invention will become thorough and complete, and will fully convey the concept of the inventive concept to those skilled in the art. In the drawings, the same reference numerals denote the same or like structures, and thus their repeated description will be omitted.

The described features, structures or characters may be combined in one or more embodiments in any suitable manner. In the following description, numerous specific details are provided so as to allow a full understanding of the embodiments of the present disclosure. However, those skilled in the art will recognize that the technical solutions of the present disclosure may be implemented without one or more of the specific details, or other methods, components, materials and so on may be used. In other cases, the well-known structures, materials or operations are not shown or described in detail to avoid obscuring various aspects of the present disclosure.

The drawings in the present disclosure are provided only to illustrate relative position relations, sizes of pixels are exaggeratedly depicted for ease understanding, sizes depicted in the drawings does not represent actual scale.

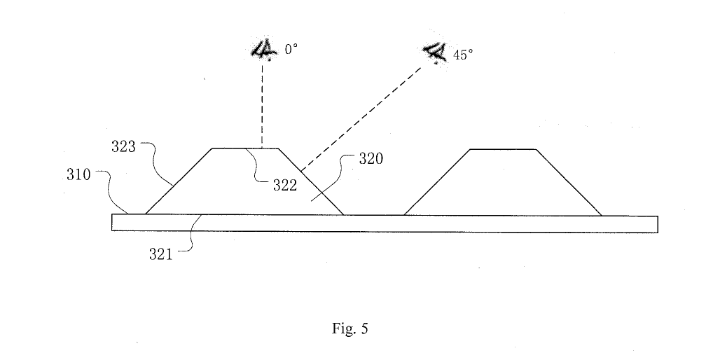

In order to improve the problem of color shift at large view angles of display panels in the prior art, the present disclosure provides a pixel array and a pixel panel including pixel units having a stereo shape. Hereinafter, methods provided in the present disclosure will be described with reference to FIGS. 5 to 10.

Firstly, referring to FIG. 5, a pixel array according to embodiments of the present disclosure is illustrated. The pixel array includes a substrate 310 and a plurality of pixel units 320. The pixel unit 320 is disposed on the substrate 310. Each pixel unit 320 has a stereo shape. In particular, each pixel unit 320 includes a first surface 321, a second surface 322 and a side wall 323. The first surface 321 faces the substrate 310. The second surface 322 is opposite to the substrate 310. Alternatively, the first surface 321 may be parallel to the second surface 322. In addition, all of the first surface 321, the second surface 322 and the side wall are optionally planar surfaces for ease of calculation and processing. The first surface 321 has an area greater than that of the second surface 322. The side wall 323 connects the first surface 321 and the second surface 322. Light emitted from each pixel unit 320 exits from the second surface 322 and the side wall 323.

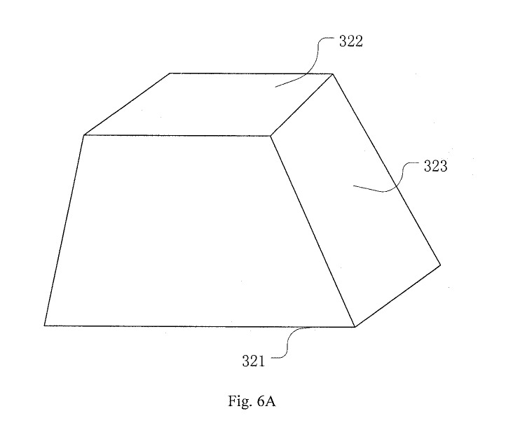

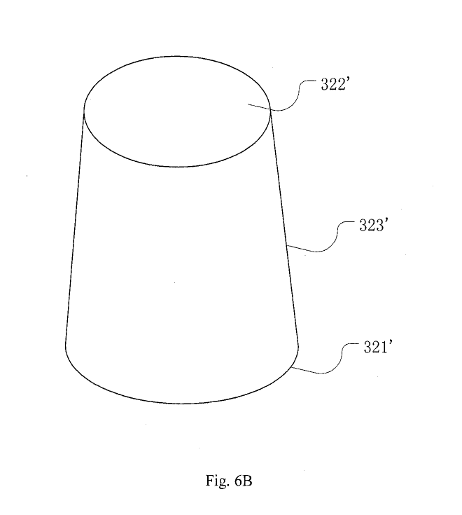

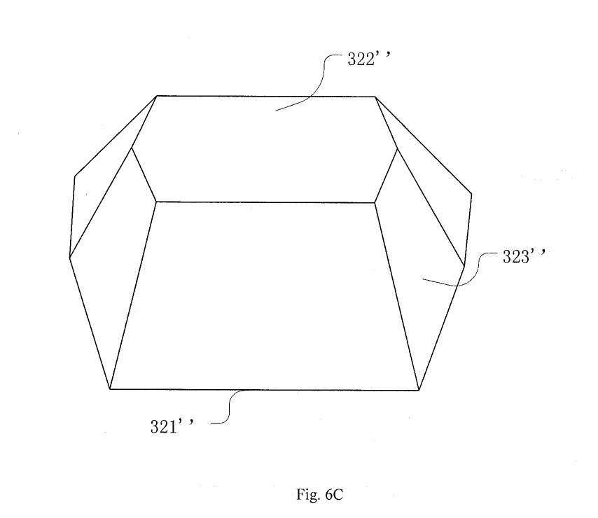

In particular, referring to FIGS. 6A to 6C, three different stereo shapes of the pixel unit are illustrated. FIG. 6A illustrates a stereo pixel unit having a truncated trapezoidal cone shape, wherein the first surface 321 and the second surface 322 are rectangular in shape, and the first surface 321 has an area greater than that of the second surface 322. In a preferred example, the first surface 321 and the second surface 322 are quadrate in shape. The side wall 323 includes four inclined surfaces connecting the first surface 321 and the second surface 322. FIG. 6B illustrates a stereo pixel unit having a truncated circular cone shape, wherein the first surface 321′ and the second surface 322′ are circular in shape. The side wall 323′ includes a truncated circular cone shaped side wall connecting the first surface 321′ and the second surface 322′. FIG. 6C illustrates a stereo pixel unit having a truncated polygonal cone shape, wherein the first surface 321″ and the second surface 322″ are polygonal in shape. The side wall 323″ includes a plurality of inclined surfaces connecting the first surface 321″ and the second surface 322″. FIGS. 6A to 6C schematically illustrate three embodiments of the stereo shape of the pixel unit, however, those skilled in the art may implement many more variable shapes.

The above pixel unit 320 having the stereo shape allows the user to see light emitted in different directions at each view angle. Since light exited in different directions have different RGB brightness decay and degrees of spectrum blue shift, a resultant effect of the light emitted in different directions visible to the user at one view angle is similar to that visible to the user at another view angle, thereby improving the problem of color shift at large view angles.

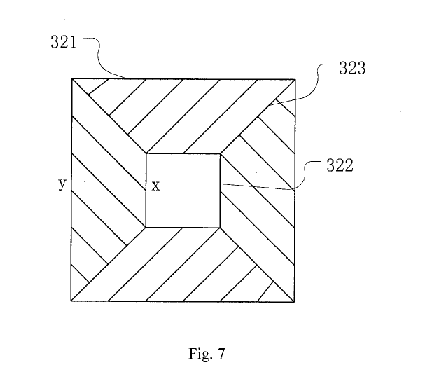

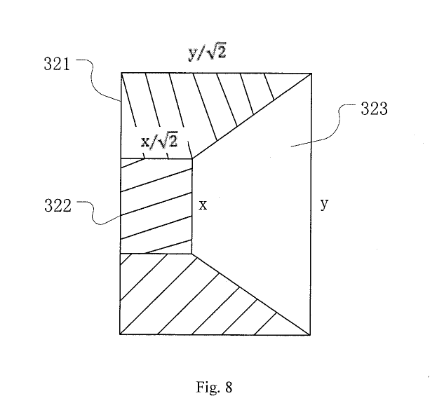

Furthermore, in order to further improve the color shift of the pixel unit between the 0 degree view angle (i.e., front view) and a large view angle, the present disclosure provides a pixel unit 320 having a shape such that ratios between an area of the straight exiting surface to that of the inclined exiting surface of the light emitted from the pixel unit 320 are identical at the 0 degree view angle and the large view angle. The straight exiting surface of the light emitted from the pixel unit 320 may change according to different view angles of the user. In particular, referring to FIGS. 7 and 8, taking the truncated trapezoidal cone shaped pixel unit 320 for example, in order to avoid color shift between the 0 degree view angle and the 45 degrees view angle of the user, a ratio between a side length y of the first surface 321 and a side length x of the second surface 322 may be calculated as follow.

Firstly, referring to FIG. 7, a pixel unit seen by the user at the 0 degree view angle is schematically illustrated, which corresponds to a projection of the pixel unit at the 0 degree view angle. In FIG. 7, the white portion indicates a straight exiting surface, i.e., an exiting surface perpendicular to the user's view angle, and has an area of the area of the second surface 322, which equals to x². The shadow portion indicates an inclined exiting surface, i.e., an exiting surface not perpendicular to the user's view angle, and has an area of the projection at 0 degree view angle of the four inclined surfaces of the side wall 323, which equals to y²−x². Accordingly, a ratio between the area of the straight exiting surface and that of the inclined exiting surface of the pixel unit 320 at the 0 degree view angle of the user is x²/(y²−x²).

Next, referring to FIG. 8, a pixel unit seen by the user at the 45 degrees view angle is schematically illustrated, which corresponds to a projection of the pixel unit at the 45 degrees view angle. In FIG. 8, the white portion indicates a straight exiting surface, i.e., an exiting surface perpendicular to the user's view angle, and has an area of the area of one inclined surface among the inclined surfaces of the side wall 323, which corresponds to 1/cos 45° times of a projection area of one inclined surface among the inclined surfaces of the side wall 323 of FIG. 7, i.e., equals to \sqrt{2}(y²−x²)/4. The shadow portion indicates an inclined exiting surface, i.e., an exiting surface not perpendicular to the user's view angle, and has an area obtained by subtracting the area of above straight exiting surface from a projection area of the first surface 321 at the 45 degrees angle, i.e., cos 45°*y², which equals to \sqrt{2}y²/\sqrt{2}−2(y²−x²)/4. Accordingly, a ratio between the area of the straight exiting surface and that of the inclined exiting surface of the pixel unit 320 at the 45 degrees view angle of the user is (y²−x²)/(y²+x²).

In order to balance the brightness difference and the spectrum blue shift between the light exited from the straight exiting surface and the inclined exiting surface at the 0 degree view angle and the 45 degrees view angle, the pixel unit 320 has an identical area ratio between the straight exiting surface and the inclined exiting surface at the 0 degree view angle and the 45 degrees view angle:

x²/(y²−x²)=(y²−x²)/(y²+x²).

According to the above equation, it can be derived that y=\sqrt{3}x. that is, in the embodiment of the truncated trapezoidal cone shaped pixel unit 320, when the first surface 321 has a side length equals to times of the side length of the second surface 322, the resultant effect of the light emitted in different directions visible to the user at 0 degree view angle and 45 degrees view angle is identical, thereby avoiding the color shift phenomenon.

The side length ratio between the first surface and the second surface of the pixel unit is exemplarily calculated above with respect the light emission of the truncated trapezoidal cone shaped pixel unit at the 0 degree view angle and 45 degrees view angle, respectively. According to the concept of the present disclosure, those skilled in the art may calculate the shape ratio of the pixel unit with respect to pixel units having different stereo shapes at the 0 degree view angle and 30 degree view angle (or other view angles), such that ratios between an area of the straight exiting surface to that of the inclined exiting surface of the light emitted from the pixel unit 320 are identical at the 0 degree view angle and the large view angle, thereby improving the color shift between the 0 degree view angle and the large view angle.

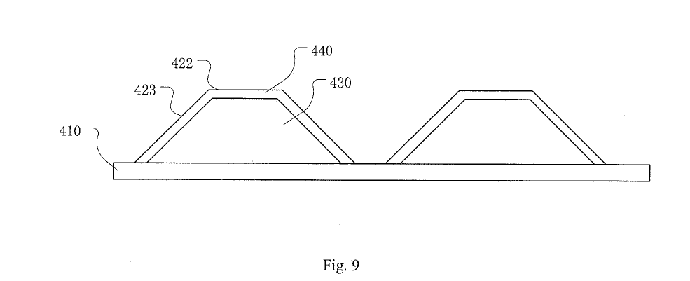

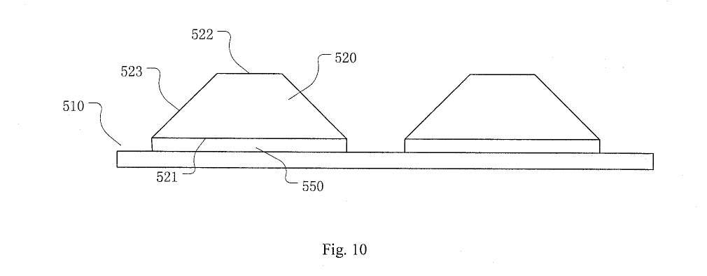

Two specific embodiments of the present disclosure are described according to FIG. 9 and FIG. 10.

FIG. 9 illustrates a schematic diagram of a pixel array according to one embodiment of the present disclosure. The pixel array includes a substrate 410 and a plurality of pixel units. The pixel unit is disposed on the substrate 410. Each pixel unit has a stereo shape such as those illustrated in FIGS. 6A to 6C. Each pixel unit includes a pixel shape defining layer 430 and a light emitting unit 440. The pixel shape defining layer 430 has a stereo shape corresponding to the pixel unit. Preferably, the pixel shape defining layer is formed of an inorganic transparent material such as silicon oxide and the like. The light emitting unit 440 covers over the pixel shape defining layer 430, such that the light emitting unit 440 may emit light externally from the second surface 422 and the side wall 423 of the pixel unit. Preferably, the light emitting unit 440 may be an OLED element.

FIG. 10 illustrates a schematic diagram of a display panel according to one embodiment of the present disclosure. The display panel includes a substrate 510, a TFT element 550 and a plurality of pixel units 520. The TFT element 550 is disposed on the substrate 510 and controls the light emission and brightness of the pixel unit 520. Each pixel unit 520 is disposed on the TFT element 550 and has a stereo shape. In the present embodiment, each pixel unit 520 includes a light emitting element, and the stereo shape of the pixel unit 520 is defined by the light emitting element. Preferably, the light emitting unit 440 may be an OLED element, and the stereo shape of the pixel unit 520 is defined by a light emitting layer of the OLED element. Light emitted from the light emitting element of the pixel unit 520 may be emitted externally from the second surface 522 and the side wall 523 of the pixel unit 520.

FIGS. 9 and 10 schematically illustrate two embodiments of the present disclosure only, and those skilled in the art may implement many more variable embodiments according to the present disclosure, which will not be repeated herein.

According to another embodiment of the present disclosure, there is further provided a pixel structure which is similar to the pixel unit as illustrated in FIGS. 6A to 6C. The pixel structure is formed on the substrate of a display panel. The pixel structure includes a first surface and a second surface parallel to one another. In one embodiment, the first surface and the second surface are connected by a side wall, and the first surface has an area greater than that of the second surface. The first surface may be a pixel shape defining layer or a surface of a light emitting element.

In comparison to the prior art, according to the present disclosure, light emitted from the pixels may exit from multiple directions by using pixels having a stereo shape, thereby reducing the ratio between areas of light exiting surfaces in the multiple directions at different view angles, which in turn may improve the problem of the RGB brightness decay and the spectrum blue shift due to large view angles and the color shift at large view angles caused due to the unevenness of the RGB brightness decay and the spectrum blue shift.

Hereinabove, exemplary implementations of the present disclosure are illustrated and described in detail. It should be appreciated that the present disclosure is not limited to the disclosed implementations, rather, the present disclosure intends to cover various modifications and equivalent alternatives included in the scope of the appended claims.

What is claimed is:

1. A pixel array, comprising:
a substrate; and
a plurality of pixel units, each of the pixel units being disposed on the substrate and comprising:
a first surface facing the substrate;
a second surface opposite to the substrate; and
a side wall connecting the first surface and the second surface,
wherein the first surface has an area greater than that of the second surface, and light from each pixel unit exits from the second surface and the side wall.

2. The pixel array according to claim 1, wherein ratios between an area of a straight exiting surface to that of an inclined exiting surface of light emitted from the pixel unit are identical at different view angles.

3. The pixel array according to claim 1, wherein each pixel unit comprises a pixel shape defining layer having a stereo shape corresponding to the pixel unit.

4. The pixel array according to claim 2, wherein each pixel unit comprises a pixel shape defining layer having a stereo shape corresponding to the pixel unit.

5. The pixel array according to claim 3, wherein the pixel shape defining layer is disposed on the substrate, and each pixel unit further comprises a light emitting element disposed on the pixel shape defining layer.

6. The pixel array according to claim 3, wherein the pixel shape defining layer is formed of an inorganic transparent material.

7. The pixel array according to claim 1, wherein each pixel unit comprises a light emitting element disposed on the substrate and having a stereo shape corresponding to the pixel unit.

8. The pixel array according to claim 2, wherein each pixel unit comprises a light emitting element disposed on the substrate and having a stereo shape corresponding to the pixel unit.

9. The pixel array according to claim 7, wherein the light emitting element is an OLED element comprising a light emitting layer having a stereo shape corresponding to the pixel unit.

10. The pixel array according to claim 8, wherein the light emitting element is an OLED element comprising a light emitting layer having a stereo shape corresponding to the pixel unit.

11. The pixel array according to claim 1, wherein the first surface and the second surface are in a polygon shape or a circular shape.

12. The pixel array according to claim 2, wherein the first surface and the second surface are in a polygon shape or a circular shape.

13. The pixel array according to claim 11, wherein the first surface and the second surface are in the same shape.

14. The pixel array according to claim 12, wherein the first surface and the second surface are in the same shape.

15. The pixel array according to claim 11, wherein the first surface and the second surface are parallel to one another.

16. The pixel array according to claim 12, wherein the first surface and the second surface are parallel to one another.

17. A display panel comprising:
a substrate;
a TFT element disposed on the substrate; and
a plurality of pixel units, each of which being disposed on the substrate and having a stereo shape, wherein each pixel unit comprises:
a first surface facing the substrate;
a second surface opposite to the substrate; and
a side wall connecting the first surface and the second surface,
wherein the first surface has an area greater than that of the second surface, and light from each pixel unit exits from the second surface and the side wall.

18. The display panel according to claim 17, wherein ratios between an area of a straight exiting surface to that of an inclined exiting surface of light emitted from the pixel unit are identical at different view angles.

19. A pixel structure formed on a substrate of a display panel, comprising a first surface and a second surface parallel to one another and connected by a side wall, wherein the first surface has an area greater than that of the second surface, and the first surface is a pixel shape defining layer or a surface of a light emitting element.

20. The pixel structure according to claim 19, wherein ratios between an area of a straight exiting surface to that of an inclined exiting surface of light emitted from the pixel structure are identical at different view angles.
